(19) United States
(12) Patent Application Publication
(10) Pub. No.: US 2019/0088852 A1
(43) Pub. Date: Mar. 21, 2019

(54) PIEZOELECTRIC DEVICE

(71) Applicant: NIHON DEMPA KOGYO CO., LTD., Tokyo (JP)

(72) Inventor: Shuichi MIZUSAWA, Saitama (JP)

(73) Assignee: NIHON DEMPA KOGYO CO., LTD., Tokyo (JP)

(21) Appl. No.: 16/132,493

(22) Filed: Sep. 17, 2018

(30) Foreign Application Priority Data
Sep. 19, 2017 (JP) 2017-178819

(51) Int. Cl. H01L 41/09; H01L 41/047; H01L 41/187; H01L 41/053

(52) U.S. Cl. CPC H01L 41/094; H01L 41/053; H01L 41/187; H01L 41/0475

(57) ABSTRACT

A piezoelectric device includes a piezoelectric vibrating piece, a ceramic base, a connection bump, and a step portion. The piezoelectric vibrating piece includes an excitation electrode and an extraction electrode that is extracted from the excitation electrode. The ceramic base has a rectangular shape in plan view and has a bottom surface and a wall surface formed from the bottom surface with a taper angle. The connection bump is formed on the bottom surface to apply a voltage to the piezoelectric vibrating piece. The step portion is arranged to be close to the connection bump in a longitudinal direction of the rectangular shape. The step portion is integrally formed with the base. The extraction electrode is connected to the connection bump with a conductive adhesive. The piezoelectric vibrating piece contacts the step portion to be obliquely supported with respect to the bottom surface in a cantilevered state.

### CROSS-REFERENCE TO RELATED APPLICATIONS

This application is based on and claims priority under 35 U.S.C. § 119 to Japanese Patent Application No. 2017-178819, filed on Sep. 19, 2017, the entire content of which is incorporated herein by reference.

### TECHNICAL FIELD

This disclosure relates to a cantilever piezoelectric device.

### DESCRIPTION OF THE RELATED ART

For example, there has been disclosed a piezoelectric device in Japanese Unexamined Patent Application Publication No. 2015-106792. This piezoelectric device has a ceramic base constituted of a plurality of stacked ceramic-based flat plates (generally, referred to as green sheets) and includes a depressed portion. In this depressed portion of the base, an extraction electrode of a piezoelectric vibrating piece is secured with a conductive adhesive. This piezoelectric vibrating piece has one end obliquely formed to be thick so as to lift the other end, thus preventing the other end from contacting a bottom surface.

However, the ceramic base in which a plurality of flat plates are stacked requires a stacking work of the flat plates, thus tending to increase cost. The problem of increasing cost also arises in that the one end of the piezoelectric vibrating piece is obliquely formed to be thick so as to lift the other end.

A need thus exists for a piezoelectric device which is not susceptible to the drawback mentioned above.

### SUMMARY

According to an aspect of this disclosure, there is provided a piezoelectric device that includes a piezoelectric vibrating piece, a ceramic base, a connection bump, and a step portion. The piezoelectric vibrating piece includes an excitation electrode and an extraction electrode. The extraction electrode is extracted from the excitation electrode. The ceramic base has a rectangular shape in plan view. The ceramic base has a bottom surface and a wall surface formed from the bottom surface with a taper angle. The connection bump is formed on the bottom surface to apply a voltage to the piezoelectric vibrating piece. The step portion is arranged to be close to the connection bump in a longitudinal direction of the rectangular shape. The step portion is integrally formed with the base. The extraction electrode is connected to the connection bump with a conductive adhesive. The piezoelectric vibrating piece contacts the step portion to be obliquely supported with respect to the bottom surface in a cantilevered state.

### BRIEF DESCRIPTION OF THE DRAWINGS

The foregoing and additional features and characteristics of this disclosure will become more apparent from the following detailed description considered with reference to the accompanying drawings.

FIG. 1A is a perspective view of a lid 20 of a piezoelectric device PD according to a first embodiment.

FIG. 1B is a perspective view of a base 10 of the piezoelectric device PD.

FIG. 1C is a sectional drawing taken along a line IC-IC in FIG. 1A and FIG. 1B.

FIG. 2A is a plan view of a piezoelectric vibrating piece 40 according to the embodiment.

FIG. 2B is a sectional drawing of the piezoelectric vibrating piece 40.

FIG. 3A is a sectional drawing describing the base and the step portion in a first example.

FIG. 3B is a sectional drawing describing the base and the step portion in a second example.

FIG. 4A is a sectional drawing describing the base and the step portion in a third example. and FIG. 4C is a plan view of the fourth example.

FIG. 4B is a sectional drawing describing the base and the step portion in a fourth example.

FIG. 4C is a plan view of the fourth example.

FIG. 5 is a flowchart of a method for manufacturing the piezoelectric device.

### DESCRIPTION OF EMBODIMENTS

The following describes embodiments of the disclosure with reference to the drawings. Each drawing used in the descriptions is merely illustrated schematically for understanding the embodiments, and a size, an angle, a thickness or similar factor is exaggeratedly illustrated in some cases. In each drawing used in the descriptions, like reference numerals designate corresponding or identical elements, and therefore such elements will not be further elaborated in some cases. Shapes, dimensions, materials, and similar factor described in the following embodiments are merely preferable examples within the scope of the disclosure.

[Configuration of Piezoelectric Device]

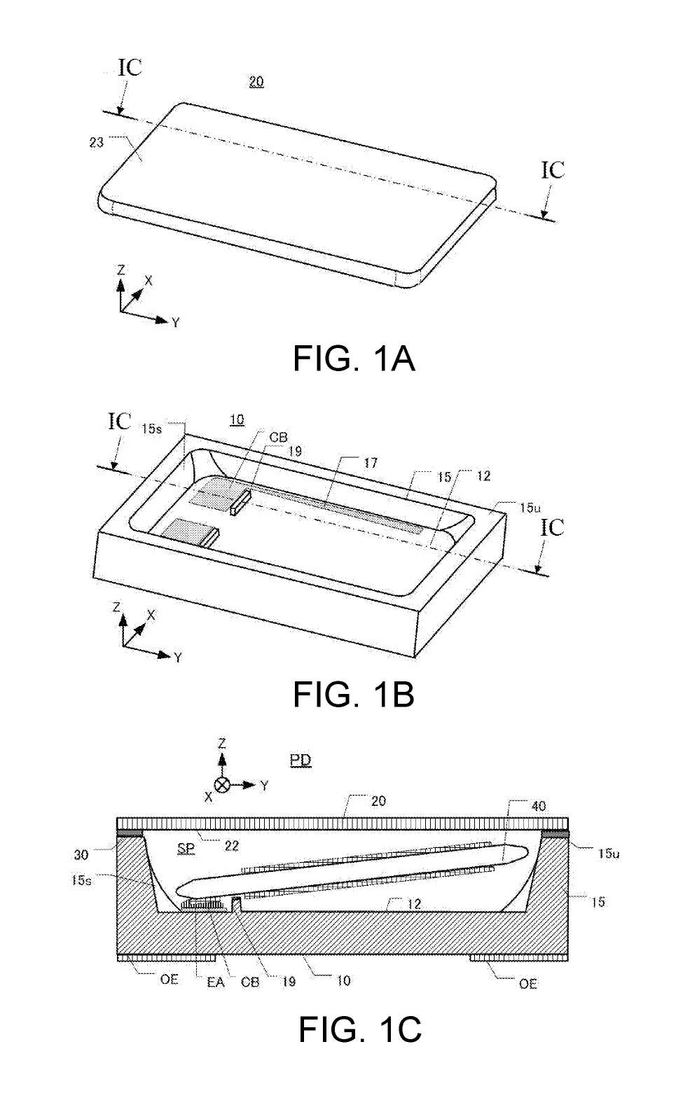

FIG. 1A is a perspective view of a lid 20 of a piezoelectric device PD according to a first embodiment, and FIG. 1B is a perspective view of a base 10 of the piezoelectric device PD. FIG. 1C is a sectional drawing of FIG. 1A and FIG. 1B, and illustrates a eutectic metal 30 and a piezoelectric vibrating piece 40 which are not illustrated in FIG. 1A and FIG. 1B.

The lid 20 illustrated in FIG. 1A and FIG. 1C has a rectangular-shaped ceiling surface 22 and an outer surface 23 on the opposite side of the ceiling surface 22. The lid 20 is constituted of a metallic material such as cobalt.

The base 10 illustrated in FIG. 1B and FIG. 1C is constituted of ceramic including, for example, alumina as a main raw material. The base 10 has a rectangular-shaped bottom surface 12, and a wall 15 is formed on four sides of the bottom surface 12. The bottom surface 12 includes a step portion 19 to incline the piezoelectric vibrating piece 40 with respect to the bottom surface 12. The step portion 19 has a height from the bottom surface 12 of 7 to 15 pin, preferably 10 μm. A connection bump CB is formed on a negative Y-axis side of the step portion 19. The piezoelectric vibrating piece 40 is bonded with a conductive adhesive EA applied over the connection bump CB. Furthermore, the base 10 includes a mounting terminal OE on a mounting surface on the opposite side of the bottom surface 12. A wiring electrode 17 extending from the connection bump CB electrically connects the connection bump CB to the mounting terminal OE by a via-wiring (not illustrated).

The eutectic metal 30 joins the base 10, on which the piezoelectric vibrating piece 40 is disposed, to the lid 20. The wall 15 of the base 10 has a top surface 15u over which paste of the eutectic metal 30 is applied. And, a wall and a flange portion of the lid 20 are arranged on the eutectic metal 30. Then, the eutectic metal 30 is sintered to join the lid 20 to the base 10. Thus, the piezoelectric vibrating piece 40 is sealed in a space SP between the lid 20 and the base 10. The sealing may be performed such that metallizing is preliminarily performed on the top surface 15u for easy joining to the eutectic alloy while a eutectic alloy layer is preliminarily formed on a region of an edge of the lid, and then, the base and the lid are joined.

The eutectic metal 30 is, for example, a gold-silicon (Au3.15Si) alloy, a gold-germanium (Au12Ge) alloy, or a gold-tin (Au20Sn) alloy. The alloyed material of the eutectic metal 30 is not specifically limited when the eutectic metal 30 has a melting point that is higher than a temperature for mounting the mounting terminal OE to an external member such as a printed board with solder alloy. Since a temperature of a reflow furnace for mounting the mounting terminal OE is generally equal to or less than 250 degrees Celsius, when the melting point of the eutectic metal 30 is equal to or more than 260 degrees Celsius, the joining of the base 10 and the lid 20 does not melt.

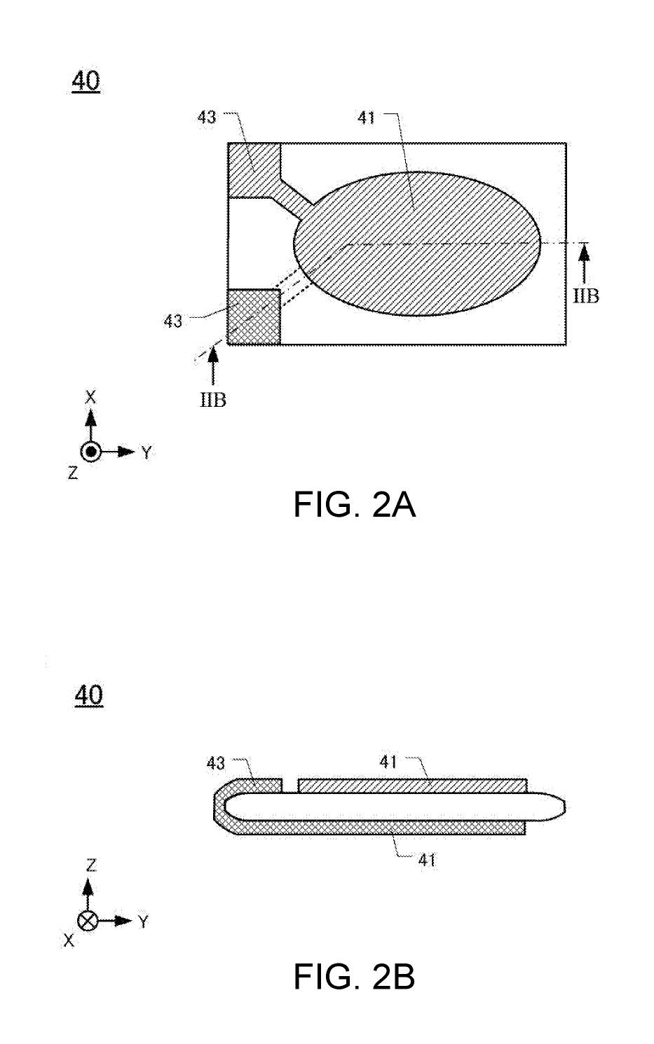

FIG. 2A is a plan view of the piezoelectric vibrating piece 40 according to the embodiment, and FIG. 2B is a sectional drawing of the piezoelectric vibrating piece 40. The piezoelectric vibrating piece 40 includes an excitation electrode 41 and an extraction electrode 43. The piezoelectric vibrating piece 40 is formed in a rectangular flat plate shape having a long side extending in a Y-axis direction and a short side extending in an X-axis direction.

The excitation electrode 41 is formed on each of front and back surfaces (each surface on a +Z-axis side) of a principal surface of the piezoelectric vibrating piece 40. The excitation electrodes 41 have an identical shape and formed so as to be mutually overlapped in the Z-axis direction. The excitation electrode 41 is formed in an elliptical shape or a square shape (not illustrated) having a long axis extending in the Y-axis direction and a short axis extending in the X-axis direction. The extraction electrode 43 is extracted from each excitation electrode 41 to each of both ends of a side of the piezoelectric vibrating piece 40 on the −Y-axis side. The extraction electrode 43 is bonded to the connection bump CB with the conductive adhesive EA and the like.

FIG. 2B is a sectional drawing taken along the line IIB-IIB in FIG. 2A. When the piezoelectric vibrating piece is a quartz-crystal vibrating piece of an AT-cut, an SC-cut, or similar cut, since a vibration frequency at which electric potential is applied to vibrate the quartz-crystal vibrating piece is inversely proportional to a thickness of a crystal element, the thickness is decided corresponding to the vibration frequency of the quartz-crystal vibrating piece. For confining a main vibration, the vibrating piece has one end side and the other end side in the Y-axis direction formed to be thin. The piezoelectric vibrating piece 40 may be a vibrating piece in the mode of vibration such as a tuning-fork type quartz-crystal vibrating piece other than the AT-cut quartz-crystal vibrating piece. When a thickness-shear vibrating piece of the AT-cut or the SC-cut is used as the piezoelectric vibrating piece 40, any vibrating piece, for example, having a uniform thickness, being performed with bevel processing, or similar vibrating piece may be employed corresponding to a design of the piezoelectric device.

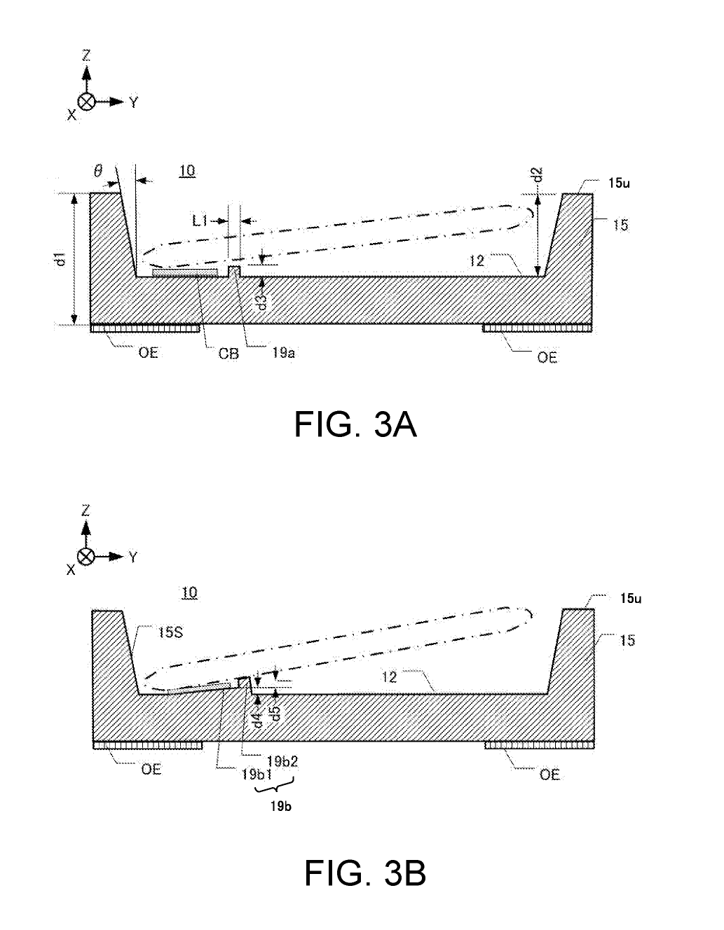

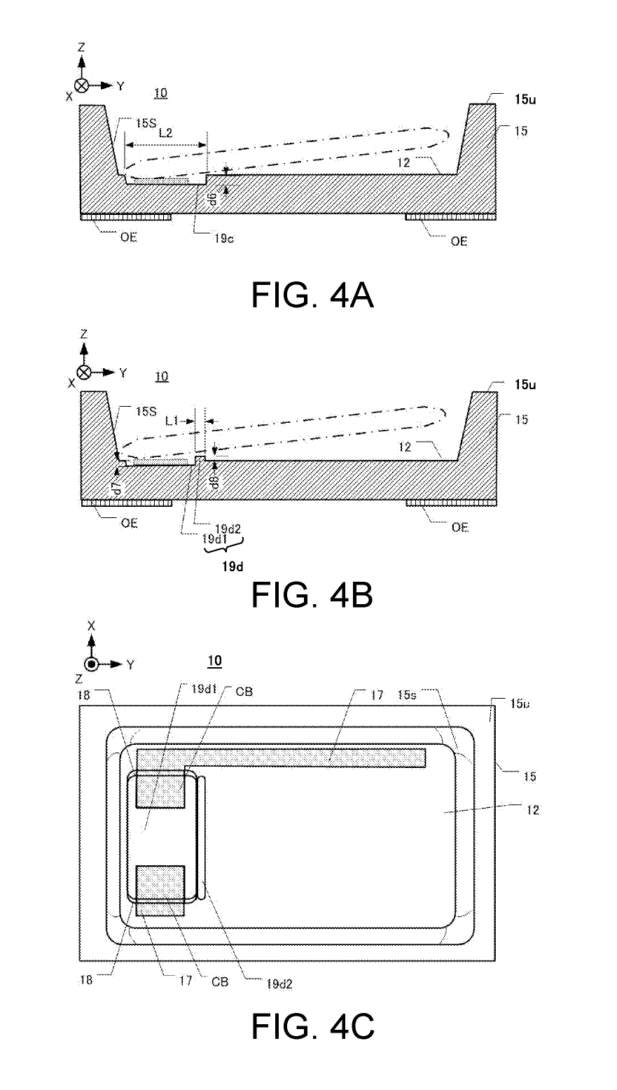

FIGS. 3A and 3B and FIGS. 4A and 4B are drawings describing a height of the wall 15 of the base 10, a taper angle of the wall 15, and the step portion 19. FIGS. 3A and 3B and FIGS. 4A and 4B are sectional drawings of positions including the step portion 19, and the piezoelectric vibrating piece 40 is illustrated by a virtual line for indicating an inclination of the piezoelectric vibrating piece 40. A first example to a fourth example illustrated in FIGS. 3A and 3B and FIGS. 4A and 4B each have the step portion 19 in different shape, while having identical height and the identical taper angle of the wall 15 of the base 10.

The base 10 has a thickness d1 that is 120 to 300 μm, preferably 120 to 200 μm. A height (or depression depth) d2 of the wall 15 from the bottom surface 12 is a height for easy pressing to form with a mold, and the height d2 is 70 to 120 μm, preferably 90 to 110 μm according to an experiment by the inventor. The wall 15 of the base 10 includes a wall surface 15s with a taper angle θ having a normal direction of the bottom surface 12 as a reference. Since a ceramic-based flat plate (a green sheet) is pressed with the mold to form the base, the ceramic base needs to be entirely removed from the mold after the pressing. According to the experiment by the inventor, the taper angle θ equal to or more than 1 degree ensures entirely removing the ceramic base. Since an excessively large taper angle θ causes a problem such as narrowing the width of the top surface 15u of the wall 15 on the base 10 or decreasing an inner volume of the base 10, an upper limit of the taper angle θ is preferred to be 5 degrees, for example.

FIG. 3A illustrates a step portion 19a as the first example of the step portion 19. As illustrated in FIG. 3A, the connection bump CB is formed in a negative Y-axis direction with respect to the bottom surface 12. The connection bump CB has a thickness (Z-axis direction) of 3 to 7 μm, and a width (Y-axis direction) of 120 to 160 μm. Two step portions 19a are disposed on a positive Y-axis direction with respect to the connection bump CB. The step portion 19a has a height d3 of 8 to 13 μm, and a width L1 (Y-axis direction) of 40 to 60 μm. A length (X-axis direction) of one step portion 19a is 80 to 120 μm. When one end of the piezoelectric vibrating piece 40 is bonded with a conductive adhesive EA, the step portion 19a obliquely cantilevers the piezoelectric vibrating piece 40. Therefore, the other end of the piezoelectric vibrating piece 40 is hard to contact the bottom surface 12 when the conductive adhesive EA hardens. In some cases, the conductive adhesive EA is applied over the connection bump CB, and the conductive adhesive EA spreads to the excitation electrode 41 on the lower surface of the piezoelectric vibrating piece 40. The spread of the conductive adhesive EA close to the excitation electrode 41 causes electrical characteristic of the piezoelectric vibrating piece 40, especially, a crystal impedance value (hereinafter referred to as a CI value) to be degraded. The step portion 19a can prevent the conductive adhesive EA from spreading to the excitation electrode 41 on the lower surface of the piezoelectric vibrating piece 40.

FIG. 3B illustrates a step portion 19b (19b1, 19b2) as the second example. As illustrated in FIG. 3B, a third step portion 19b1 is formed to have an inclined surface that becomes higher in the Z-axis direction from the bottom surface 12 toward the Y-axis direction. The third step portion 19b1 including the inclined surface has a height d4 of 4 to 10 μm, and a width (Y-axis direction) of 120 to 160 μm. The third step portion 19b1 has a length (X-axis direction) of 450 to 550 μm. Two connection bumps CB are formed on the one third step portion 19b1, and the connection bumps CB are identical to the first example in size. The wiring electrode 17 is arranged on a stepless portion of the third step portion 19b1 of the bottom surface 12. Furthermore, a fourth step portion 19b2 is disposed on a positive Y-axis side with respect to the third step portion 19b1. The fourth step portion 19b2 has a height d5 of 3 to 8 μm, and a width L1 (Y-axis direction) of 40 to 60 μm. The fourth step portion 19b2 has a length of 450 to 550 μm similar to the third step portion 19b1. When one end of the piezoelectric vibrating piece 40 is bonded with a conductive adhesive EA, the third step portion 19b1 and the fourth step portion 19b2 obliquely cantilever the piezoelectric vibrating piece 40. Therefore, the other end of the piezoelectric vibrating piece 40 is hard to contact the bottom surface 12 when the conductive adhesive EA hardens. Then, the fourth step portion 19b2 can prevent the conductive adhesive EA from spreading to the excitation electrode 41 on the lower surface of the piezoelectric vibrating piece 40.

FIG. 4A illustrates a step portion 19c as the third example. As illustrated in FIG. 4A, the step portion 19c is formed on the negative Y-axis direction with respect to the bottom surface 12 so as to be lower (negative Z-axis direction) than the bottom surface 12. The step portion 19c has a depth d6 of 8 to 18 μm, and a width L2 (Y-axis direction) of 140 to 200 μm. The step portion 19c has a length of 450 to 550 μm. Two connection bumps CB are formed on the one step portion 19c. The connection bump CB has a thickness (Z-axis direction) of 3 to 7 μm, and a width (Y-axis direction) of 120 to 160 μm. When one end of the piezoelectric vibrating piece 40 is bonded with a conductive adhesive EA, the step portion 19c obliquely cantilevers the piezoelectric vibrating piece 40. Therefore, the other end of the piezoelectric vibrating piece 40 is hard to contact the bottom surface 12 when the conductive adhesive EA hardens. Then, the step portion 19c can prevent the conductive adhesive EA from spreading to the excitation electrode 41 on the lower surface of the piezoelectric vibrating piece 40.

FIG. 4B illustrates a step portion 19d (19d1, 19d2) as the fourth example. As illustrated in FIG. 4B, a first step portion 19d1 is formed on the negative Y-axis direction with respect to the bottom surface 12 so as to be lower (negative Z-axis direction) than the bottom surface 12. The first step portion 19d1 has a depth d7 of 4 to 10 μm, and a width L1 (Y-axis direction) of 140 to 200 μm. The first step portion 19d1 has a length (X-axis direction) of 450 to 550 μm. Two connection bumps CB are formed on the one first step portion 19d1, and the connection bumps CB are identical to the second example in size. A second step portion 19d2 is disposed on a positive Y-axis side with respect to the first step portion 19d1. The second step portion 19d2 has a height d8 of 3 to 8 μm, and a width L1 (Y-axis direction) of 40 to 60 μm. The second step portion 19d2 has a length of 450 to 550 μm similar to the first step portion 19d1. When one end of the piezoelectric vibrating piece 40 is bonded with a conductive adhesive EA, the first step portion 19d1 and the second step portion 19d2 obliquely cantilever the piezoelectric vibrating piece 40. Therefore, the other end of the piezoelectric vibrating piece 40 is hard to contact the bottom surface 12 when the conductive adhesive EA hardens. Then, the first step portion 19d1 and the second step portion 19d2 can prevent the conductive adhesive EA from spreading to the excitation electrode 41 on the lower surface of the piezoelectric vibrating piece 40.

Both step portion 19c as the third example and first step portion 19d1 as the fourth example are disposed on the negative Y-axis direction with respect to the bottom surface 12. Then, the step portion 19c or the first step portion 19d1 need to avoid disconnection of the electrical connection between the two connection bumps CB and the wiring electrode 17. Therefore, as illustrated in FIG. 4C, slopes 18 may be formed on the positive and negative X-axis direction with respect to the step portion 19c or the first step portion 19d1. Disposing the wiring electrode 17 on the slope 18 prevents the wiring electrode 17 extending from the connection bump CB from being cut.

[Method for Manufacturing Piezoelectric Device]

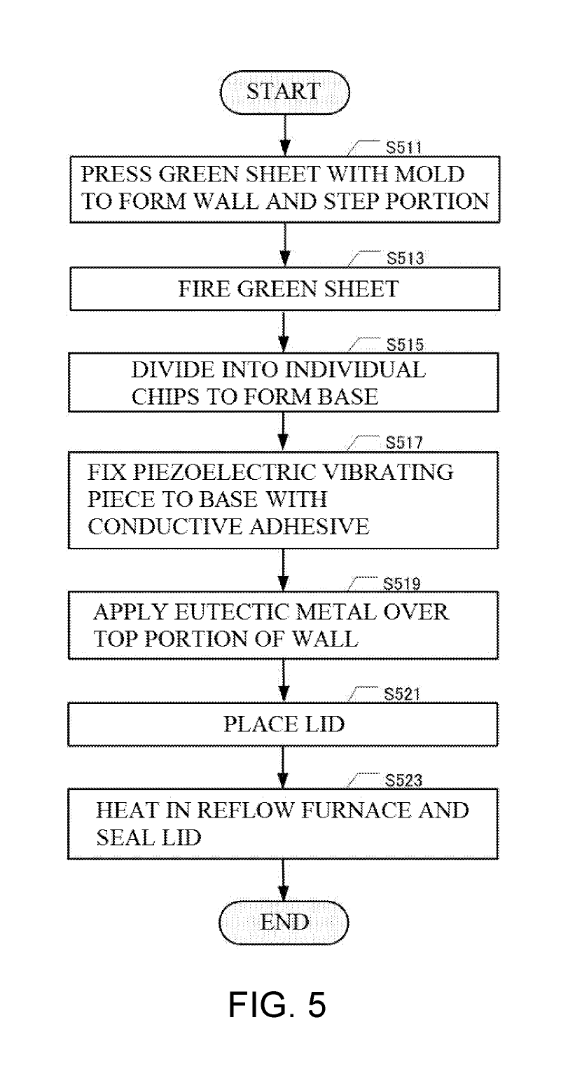

Next, a method for manufacturing the piezoelectric device will be described with reference to FIG. 5. FIG. 5 especially describes manufacturing of the base 10 of the piezoelectric device PD in detail.

First, a ceramic-based flat plate (a green sheet) having a predetermined thickness is prepared. Tungsten or similar material for the connection bump CB has been already applied over the ceramic-based flat plate, and gold plating or similar processing has been performed. The ceramic-based flat plate is pressed with a mold (not illustrated) for the base 10. Then, the wall 15 and the step portion 19 (19a, 19b, 19c, 19d) of the base 10 are formed (Step S511). A plurality of molds have been prepared corresponding to various kinds of the step portion 19 (19a, 19b, 19c, 19d).

Next, the ceramic-based flat plate is fired (Step S513). At this time, the connection bump CB and the mounting terminal OE are formed as well. Then, the ceramic-based flat plate is divided into individual chips to form the base 10 (Step S515). The conductive adhesive EA is applied over the connection bump CB of the base 10. Then, the extraction electrode of the piezoelectric vibrating piece 40 is placed so as to be overlapped on the connection bump CB, over which the conductive adhesive EA has been already applied, and the conductive adhesive EA is hardened to fix the piezoelectric vibrating piece 40 to the base 10 (Step S517).

Next, the eutectic metal 30 having the melting point equal to or more than 260 degrees Celsius is applied over the top surface 15u of the wall 15 of the base 10 on which the piezoelectric vibrating piece 40 has been already bonded (Step S519). Then, in a vacuum or predetermined gas atmosphere, the flange portion of the lid 20 is placed so as to be overlapped on the top surface 15u (Step S521). In the state where the lid 20 is stacked on the base 10, the lid and the base are put into the reflow furnace. Then, the eutectic metal 30 is heated to equal to or more than 260 degrees Celsius in the reflow furnace to be melted, and the base and the lid seal the piezoelectric vibrating piece 40 (Step S523). Thus, the piezoelectric device PD is manufactured.

While the piezoelectric device and the method for manufacturing the piezoelectric device of the embodiment are described above, this disclosure is not limited to the above-described embodiment. For example, in the above-described example, the crystal unit is especially described as the piezoelectric device. However, this disclosure is applicable to a crystal controlled oscillator that includes a transmitter, and further, a piezoelectric resonator or a piezoelectric oscillator that uses a piezoelectric material other than the crystal. For example, in a case where the lid is grounded or similar case, a routing wiring for grounding may be disposed in the piezoelectric device and a mounting terminal for grounding may be disposed on an outer bottom surface of the base.

The connection bump may be formed on a surface lower than the bottom surface, and the step portion is formed on a surface identical to the bottom surface or a surface formed to be higher than the bottom surface.

The connection bump may be formed on a surface identical to the bottom surface, and the step portion may be formed to be higher than the bottom surface.

Furthermore, the bottom surface may include an inclined surface inclined from the bottom surface in the longitudinal direction of the rectangular shape, and the connection bump and the step portion may be formed on the inclined surface.

Furthermore, a wiring electrode may be disposed so as to extend from a region where the inclined surface and the bottom surface are continuous without a step, and the wiring electrode may extend from the connection bump.

The piezoelectric device of this disclosure can reduce manufacturing cost.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric device, comprising:
a piezoelectric vibrating piece that includes an excitation electrode and an extraction electrode, and the extraction electrode being extracted from the excitation electrode;
a ceramic base, having a rectangular shape in plan view, and the ceramic base having a bottom surface and a wall surface, and the wall surface being formed from the bottom surface with a taper angle;
a connection bump, being formed on the bottom surface to apply a voltage to the piezoelectric vibrating piece; and
a step portion, being arranged to be close to the connection bump in a longitudinal direction of the rectangular shape, and the step portion being integrally formed with the base,
wherein the extraction electrode is connected to the connection bump with a conductive adhesive, and
the piezoelectric vibrating piece contacts the step portion to be obliquely supported with respect to the bottom surface in a cantilevered state.

2. The piezoelectric device according to claim 1, wherein
the connection bump is formed on a surface lower than the bottom surface, and
the step portion is formed on a surface identical to the bottom surface or a surface formed to be higher than the bottom surface.

3. The piezoelectric device according to claim 1, wherein
the connection bump is formed on a surface identical to the bottom surface, and
the step portion is formed to be higher than the bottom surface.

4. The piezoelectric device according to claim 1, wherein
the bottom surface includes an inclined surface inclined from the bottom surface in the longitudinal direction of the rectangular shape, and
the connection bump and the step portion are formed on the inclined surface.

5. The piezoelectric device according to claim 4, further comprising:
a wiring electrode extending from a region where the inclined surface and the bottom surface are continuous without a step, and the wiring electrode extending from the connection bump.

6. The piezoelectric device according to claim 1, wherein
the base is formed by firing after a ceramic green sheet is pressed with a mold to form the wall surface.
